(19) United States
(12) Patent Application Publication
(10) Pub. No.: US 2022/0284237 A1
(43) Pub. Date: Sep. 8, 2022

(54) RESTRICTED BOLTZMANN MACHINE BASED SOURCE-SEPARATION MODEL WITH APPLICATION TO LOAD DISAGGREGATION

(71) Applicant: Tata Consultancy Services Limited, Mumbai (IN)

(72) Inventors: Spoorthy Paresh, Bangalore (IN); Naveen Thokala, Hyderabad (IN); Vishnu Brindavanam, Telangana (IN); Mariswamy Girish Chandra, Hyderabad (IN)

(73) Assignee: Tata Consultancy Services Limited, Mumbai (IN)

(21) Appl. No.: 17/453,316

(22) Filed: Nov. 2, 2021

(30) Foreign Application Priority Data
Feb. 4, 2021 (IN) 202121004907

(51) Int. Cl. G06K 9/62; G06N 3/04; G01R 21/133

(52) U.S. Cl. CPC G06K 9/6256; G06K 9/6228; G06N 3/04; G01R 21/1336

(57) ABSTRACT

Load disaggregation is useful for both the consumers and producers of energy. The present-day supervised learning models for load disaggregation necessitate the learning of models for every appliance load of interest, which incurs high computational costs. Embodiments of the present disclosure implement a Restricted Boltzmann Machine (RBM) based source-separation model with application to load disaggregation of appliances of interest. Representations of appliance of interest are learnt, between the power aggregate data and the appliance signatures, to output the mapping of data representations on the appliance signatures, for load disaggregation. Discriminative ability for each load/appliance of interest is achieved by adding the free energies of softmax layers of the RBM on other loads/appliance, as a discriminating gradient to the approximate gradients obtained on the load under consideration.

### PRIORITY CLAIM

This U.S. patent application claims priority under 35 U.S.C. § 119 to: India Application No. 202121004907, filed on Feb. 4, 2021. The entire contents of the aforementioned application are incorporated herein by reference.

### TECHNICAL FIELD

The disclosure herein generally relates to load disaggregation, and, more particularly, to system and method that implement a Restricted Boltzmann Machine (RBM) based source-separation model with application to load disaggregation.

### BACKGROUND

Over the years, there has been an increase in interest in energy-efficient infrastructures and this is driving the research works in the field of load disaggregation. While attempts are being made to conserve energy, the focus has also been on how best the electricity consumption can be optimized by each appliance. Load disaggregation may be useful in terms of both the consumers and producers of energy. The present-day supervised learning models for load disaggregation necessitate the learning of models for every appliance load of interest, which incurs high computational costs. Also, the amount of training data that is available in real-life is scarce and the models must be built with such a constraint in mind. The presence of common states like motor operation in certain appliances, are likely to make the supervised models vulnerable to errors; therefore, a trade-off between supervised and unsupervised is intended. Such models can easily adapt to Out of Distribution (OOD) which is a necessary criterion for problem at hand.

### SUMMARY

Embodiments of the present disclosure present technological improvements as solutions to one or more of the above-mentioned technical problems recognized by the inventors in conventional systems. For example, in one aspect, there is provided a processor implemented method for load disaggregation of appliances of interest. The method comprises: receiving, via one or more hardware processors, an input comprising power consumption of a first set of appliances deployed in an infrastructure for a specific time period; obtaining, via the one or more hardware processors, information pertaining one or more power consumption patterns specific to a second set of appliances; learning, via a Restricted Boltzmann Machine (RBM) executed by the one or more hardware processors, (i) one or more representations of one or more appliances of interest (AoI), wherein the one or more AoI are subset of at least one of the first set of appliances and the second set of appliances, wherein each softmax layer comprised in the RBM learns a representation of a corresponding AoI from the one or more AoI based on a discriminative output obtained from remaining one or more softmax layers of the RBM; mapping, via one or more full connected layers of a neural network executed by the one or more hardware processors, the one or more learned representations to a corresponding power consumption pattern from the one or more power consumption patterns to obtain one or more mapped appliance consumption patterns for each of the one or more AoI; and estimating, via the one or more hardware processors, one or more appliance signatures for the one or more AoI based on the one or more mapped appliance consumption patterns.

In an embodiment, the appliance signature is indicative or comprises an identifier and power consumption associated with an AoI from the one or more AoI.

In an embodiment, the one or more representations comprise power consumption of the one or more AoI.

In an embodiment, the method further comprises triggering the appliances for scheduling on and off based on the appliance signatures.

In an embodiment, the method further comprises obtaining (i) softmax information of a plurality of appliances from the first set and the second set of appliances, wherein the softmax information is obtained through one visible layer of the RBM connected to the one or more softmax layers, and (ii) a partition function serving as an output of another visible layer of the RBM; and learning, via an intermediate function, one or more combinational outputs of each of the one or more RBMs based on an interaction between the softmax information and the partition function.

In one aspect, there is provided a system for load disaggregation of appliances of interest. The system comprises: a memory storing instructions; one or more communication interfaces; and one or more hardware processors coupled to the memory via the one or more communication interfaces, wherein the one or more hardware processors are configured by the instructions to: receive an input comprising power consumption of a first set of appliances deployed in an infrastructure for a specific time period; obtain information pertaining one or more power consumption patterns specific to a second set of appliances; learning, via a Restricted Boltzmann Machine (RBM) executed by the one or more hardware processors, (i) one or more representations of one or more appliances of interest (AoI), wherein the one or more AoI are subset of at least one of the first set of appliances and the second set of appliances, wherein each softmax layer comprised in the RBM learns a representation of a corresponding AoI from the one or more AoI based on a discriminative output obtained from remaining one or more softmax layers of the RBM; map, via one or more full connected layers of a neural network executed by the one or more hardware processors, the one or more learned representations to a corresponding power consumption pattern from the one or more power consumption patterns to obtain one or more mapped appliance consumption patterns for each of the one or more AoI; and estimate one or more appliance signatures for the one or more AoI based on the one or more mapped appliance consumption patterns.

In an embodiment, the appliance signature is indicative or comprises an identifier and power consumption associated with an AoI from the one or more AoI.

In an embodiment, the one or more representations comprise power consumption of the one or more AoI.

In an embodiment, the instructions are configured by the one or more hardware processors to trigger the appliances for scheduling on and off based on the appliance signatures.

In an embodiment, the instructions are configured by the one or more hardware processors to trigger obtain (i) softmax information of a plurality of appliances from the first set and the second set of appliances, wherein the softmax information is obtained through one visible layer of the RBM connected to the one or more softmax layers, and (ii) a partition function serving as an output of another visible layer of the RBM; and learn, via an intermediate function, one or more combinational outputs of each of the one or more RBMs based on an interaction between the softmax information and the partition function.

In yet another aspect, there are provided one or more non-transitory machine readable information storage mediums comprising one or more instructions which when executed by one or more hardware processors causes load disaggregation of appliances of interest by receiving, via the one or more hardware processors, an input comprising power consumption of a first set of appliances deployed in an infrastructure for a specific time period; obtaining, via the one or more hardware processors, information pertaining one or more power consumption patterns specific to a second set of appliances; learning, via a Restricted Boltzmann Machine (RBM) executed by the one or more hardware processors, (i) one or more representations of one or more appliances of interest (AoI), wherein the one or more AoI are subset of at least one of the first set of appliances and the second set of appliances, wherein each softmax layer comprised in the RBM learns a representation of a corresponding AoI from the one or more AoI based on a discriminative output obtained from remaining one or more softmax layers of the RBM; mapping, via one or more full connected layers of a neural network executed by the one or more hardware processors, the one or more learned representations to a corresponding power consumption pattern from the one or more power consumption patterns to obtain one or more mapped appliance consumption patterns for each of the one or more AoI; and estimating, via the one or more hardware processors, one or more appliance signatures for the one or more AoI based on the one or more mapped appliance consumption patterns.

In an embodiment, the appliance signature is indicative or comprises an identifier and power consumption associated with an AoI from the one or more AoI.

In an embodiment, the one or more representations comprise power consumption of the one or more AoI.

In an embodiment, the instructions which when executed further cause the hardware processors to trigger the appliances for scheduling on and off based on the appliance signatures.

In an embodiment, The instructions which when executed further cause the hardware processors to obtain (i) softmax information of a plurality of appliances from the first set and the second set of appliances, wherein the softmax information is obtained through one visible layer of the RBM connected to the one or more softmax layers, and (ii) a partition function serving as an output of another visible layer of the RBM; and learn, via an intermediate function, one or more combinational outputs of each of the one or more RBMs based on an interaction between the softmax information and the partition function.

It is to be understood that both the foregoing general description and the following detailed description are exemplary and explanatory only and are not restrictive of the invention, as claimed.

### BRIEF DESCRIPTION OF THE DRAWINGS

The accompanying drawings, which are incorporated in and constitute a part of this disclosure, illustrate exemplary embodiments and, together with the description, serve to explain the disclosed principles:

FIG. 1 depicts a system for load disaggregation of appliances of interest using a Restricted Boltzmann Machine (RBM) based source-separation model, in accordance with an embodiment of the present disclosure.

FIG. 2 depicts an exemplary flow chart illustrating a method for load disaggregation of appliances of interest using the Restricted Boltzmann Machine (RBM) based source-separation model, using the system of FIG. 1, in accordance with an embodiment of the present disclosure.

### DETAILED DESCRIPTION

Exemplary embodiments are described with reference to the accompanying drawings. In the figures, the left-most digit(s) of a reference number identifies the figure in which the reference number first appears. Wherever convenient, the same reference numbers are used throughout the drawings to refer to the same or like parts. While examples and features of disclosed principles are described herein, modifications, adaptations, and other implementations are possible without departing from the scope of the disclosed embodiments.

Over the years, there has been an increase in interest in energy-efficient infrastructures and this is driving the research works in the field of load disaggregation. While attempts are being made to conserve energy, the focus has also been on how best the electricity consumption can be optimized by each appliance.

Load disaggregation may be useful in terms of both the consumers and producers of energy. The present-day supervised learning models for load disaggregation necessitate the learning of models for every appliance load of interest, which incurs high computational costs. Also, the amount of training data that is available in real-life is scarce and the models must be built with such a constraint in mind. The presence of common states like motor operation in certain appliances, are likely to make the supervised models vulnerable to errors; therefore, a trade-off between supervised and unsupervised is intended. Such models can easily adapt to OOD which is necessary criterion for problem at hand.

Embodiments of the present disclosure provide system and method that implement a Restricted Boltzmann Machine (RBM) based source-separation model with application to load disaggregation of appliances of interest. More specifically, the present disclosure provides a system and method for cognitive processing-based load disaggregation that use Restricted Boltzmann Machine (RBM) in a discriminative setup to obtain the semi-supervised approach to load disaggregation. Representations are learnt in an alternating fashion, between the power aggregate data and the appliance signatures, to output the mapping of data representations on the appliance signatures, for load disaggregation. Discriminative ability for each load/appliance of interest is achieved by adding the free energies of softmax layers of the RBM on other loads/appliance, as a discriminating gradient to the approximate gradients obtained on the load under consideration.

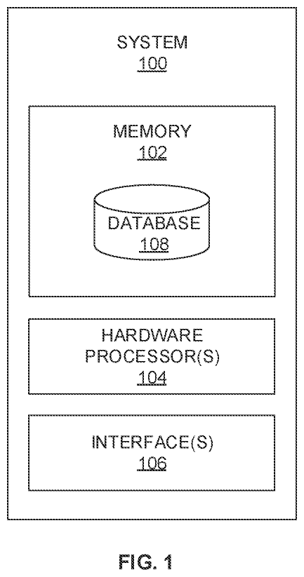

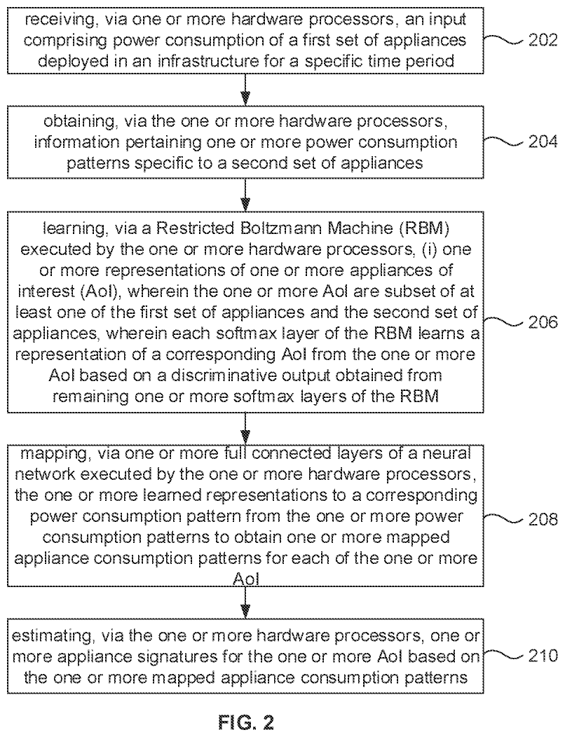

Referring now to the drawings, and more particularly to FIGS. 1 through 2, where similar reference characters denote corresponding features consistently throughout the figures, there are shown preferred embodiments and these embodiments are described in the context of the following exemplary system and/or method.

FIG. 1 depicts a system 100 for load disaggregation of appliances of interest using a Restricted Boltzmann Machine (RBM) based source-separation model, in accordance with an embodiment of the present disclosure. In an embodiment, the system 100 includes one or more hardware processors 104, communication interface device(s) or input/output (I/O) interface(s) 106 (also referred as interface(s)), and one or more data storage devices or memory 102 operatively coupled to the one or more hardware processors 104. The one or more processors 104 may be one or more software processing components and/or hardware processors. In an embodiment, the hardware processors can be implemented as one or more microprocessors, microcomputers, microcontrollers, digital signal processors, central processing units, state machines, logic circuitries, and/or any devices that manipulate signals based on operational instructions. Among other capabilities, the processor(s) is/are configured to fetch and execute computer-readable instructions stored in the memory. In an embodiment, the system 100 can be implemented in a variety of computing systems, such as laptop computers, notebooks, hand-held devices, workstations, mainframe computers, servers, a network cloud and the like.

The I/O interface device(s) 106 can include a variety of software and hardware interfaces, for example, a web interface, a graphical user interface, and the like and can facilitate multiple communications within a wide variety of networks N/W and protocol types, including wired networks, for example, LAN, cable, etc., and wireless networks, such as WLAN, cellular, or satellite. In an embodiment, the I/O interface device(s) can include one or more ports for connecting a number of devices to one another or to another server.

The memory 102 may include any computer-readable medium known in the art including, for example, volatile memory, such as static random-access memory (SRAM) and dynamic random-access memory (DRAM), and/or non-volatile memory, such as read only memory (ROM), erasable programmable ROM, flash memories, hard disks, optical disks, and magnetic tapes. In an embodiment, a database 108 is comprised in the memory 102, wherein the database 108 comprises input received by the system 100 in terms of smart meter data corresponding to a set of appliances. The database 108 further stores power consumption patterns corresponding to another set of appliances. The database 108 further stores information related to learning of one or more representations, discriminative output(s) of the RBM, mapped appliance power consumption patterns for each of appliance of interest, appliance signature(s), scheduling ON and OFF information specific to various appliances of interest, softmax information and partition function associated with the RBM, combinational outputs associated with softmax layers of the RBM, and the like.

The information stored in the database 108 further comprises various techniques such as scheduling technique(s) for scheduling ON and OFF of appliances for optimum utilization, propagation technique(s) (e.g., back propagation technique and the like) as known in the art, and the like. The above-mentioned techniques comprised in the memory 102/database 108 are invoked as per the requirement by the system 100 to perform the methodologies described herein. The memory 102 further comprises (or may further comprise) information pertaining to input(s)/output(s) of each step performed by the systems and methods of the present disclosure. In other words, input(s) fed at each step and output(s) generated at each step are comprised in the memory 102 and can be utilized in further processing and analysis.

FIG. 2 depicts an exemplary flow chart illustrating a method for load disaggregation of appliances of interest using a Restricted Boltzmann Machine (RBM) based source-separation model, using the system 100 of FIG. 1, in accordance with an embodiment of the present disclosure. In an embodiment, the system(s) 100 comprises one or more data storage devices or the memory 102 operatively coupled to the one or more hardware processors 104 and is configured to store instructions for execution of steps of the method by the one or more processors 104. The steps of the method of the present disclosure will now be explained with reference to components of the system 100 of FIG. 1, and the flow diagram as depicted in FIG. 2. In an embodiment, at step 202 of the present disclosure, the one or more hardware processors 104 receive an input (e.g., smart meter data) comprising power consumption of a first set of appliances deployed in an infrastructure for a specific time-period (or time interval). Example of the input power consumption pattern of the first set of appliances include but are not limited to: (i) a refrigerator typically consuming 150˜200 watts in the normal state, microwave usually registers a spike of 1000˜1500 watts, a washer-dryer register a magnitude of 1500 watts approximately, followed by cyclic consumption states in the range (>500 ˜<1000 watts). It is to be understood by a person having ordinary skill in the art or person skilled in the art that the above example of smart meter data/power consumption pattern of the first set of appliances are typical magnitudes and may differ with appliance make/manufacture slightly. Nevertheless, the patterns of consumption remain the same, in one example embodiment. In an embodiment, expressions consumption pattern and power consumption pattern may be interchangeably used herein.

In an embodiment, at step 204 of the present disclosure, the one or more hardware processors 104 obtain information (e.g., from a publicly available dataset) pertaining one or more power consumption patterns specific to a second set of appliances. In an embodiment of the present disclosure, the system 100 collects historical aggregate and appliance signature data and segments them into N-length windows. The appliance data is usually collected such that it is representative of the usual power consumption patterns in the household, in one example embodiment. Example of infrastructures such as household(s) shall not be construed as limiting the scope of the present disclosure. In other words, the present disclosure may obtain smart meter data at step 202, and information from the publicly available dataset at step 204 from various premises such as corporate buildings, shopping malls, retail outlets, government offices, and the like. If a consumption vector comprising of 150˜200 watts is observed for a period of one hour and a spike of 2000 watts appears thereafter towards the end of the observational window in the input aggregate data, the same is captured through a series of internal updations within the RBM till the point of obtaining a partition function and subsequently free energy (F_{c}). The first set of appliances and the second set of appliances may be different from each other, in one embodiment. The first set of appliances and the second set of appliances are identical, in another embodiment. The first set of appliances and the second set of appliances have at least a few appliances in common in terms of make, specification, brand, and the like, in yet another embodiment.

In an embodiment, at step 206 of the present disclosure, the one or more hardware processors 104 learn, via a RBM executed by the one or more hardware processors, one or more representations of one or more appliances of interest (AoI) to obtain one or more learned representations. The one or more representations comprise magnitude as mentioned above in step 202. In other words, the one or more representations comprise power consumption (or power consumption pattern) associated with a corresponding AoI, in one embodiment of the present disclosure. The one or more AoI are subset of at least one of the first set of appliances and the second set of appliances. In other words, the one or more AoI are subset of either the first set of appliances, or the second set of appliances or subset of the combinations thereof. In an embodiment, each softmax layer of the RBM learns a representation of a corresponding AoI from the one or more AoI based on a discriminative output obtained from remaining one or more softmax layers of the RBM. In one embodiment, each softmax layer of the RBM learns a representation of a corresponding AoI from the one or more AoI based on a discriminative output obtained from remaining one or more softmax layers amongst ‘n’ softmax layers of the RBM. Below description illustrates a process of inputting historical data (e.g., information obtained from the publicly available dataset) to the RBM and the appliance information is fed to various softmax layers of the RBM:

When the historical aggregate data is passed into a visible layer of the RBM, the partition function is computed and along with it the approximate gradients for the input aggregate data is also obtained. The historical aggregate data is transformed using the RBM and the free energy (F_{c}) is observed for the training period. Each of the softmax layers also registers non-linear transformation(s) for different appliance(s). The combinational transformations are learnt as a representation of the free energy of the RBM through a likelihood maximization approach/algorithm (e.g., the present disclosure implements likelihood maximization approach as known in the art).

On the other end of the RBM, softmax layers—each trained on an appliance's historical consumption data connected in parallel. The output of the softmax layers is related to the free energy of the RBM through an intermediate function. Through this function the occurrence of a windowed consumption Pₗ is related to the associated consumption contribution of all the appliances. If appliance Aᵢ→Aₖ was operational (or subset of the total set of appliances were operational), the disaggregated results are obtained through likelihood maximization objective function between the partition function due to aggregate data and the non-linear transformed states of appliances, which is equal to the least free energy combination of the appliance(s) of the RBM framework of the present disclosure.

Referring to the steps of FIG. 2, at step 208 of the present disclosure, the one or more hardware processors 104 map, via one or more full connected layers of a neural network executed by the one or more hardware processors, the one or more learned representations to a corresponding power consumption pattern from the one or more consumption patterns to obtain one or more mapped appliance consumption patterns (also referred as mapped appliance power consumption pattern) for each of the one or more AoI The neural network (not shown in FIGS.) is comprised in the memory 102. As discussed above, on the other end, the softmax layers register the non-linear transformations for the power consumption patterns of different appliances of interest. Assuming that the appliances of interest are refrigerator, washer-dryer, microwave for this experiment. If during this window of observation for the aggregate data, if refrigerator was operational and registered the 150˜200 watts and towards the end of the window if microwave was operated, the non-linearly transformed output of the softmax layers convey the same information (which is mapping information for each of the appliance of interest—in this case refrigerator, washer-dryer, microwave, and the like).

Referring to the steps of FIG. 2, at step 210 of the present disclosure, the one or more hardware processors 104 estimate one or more appliance signatures for the one or more AoI based on the one or more mapped appliance consumption patterns. the appliance signature is indicative or comprises an identifier and power consumption associated with an AoI. More specifically, the present disclosure and its system and the method use/implement a propagation technique/an efficient (appropriate) objective function or a backward propagation algorithm (the aforesaid intermediate function), to associate the free energy (F_{c}) with the softmax outputs. The combination of such associations yields least energy corresponds to the combination of appliances contributing to the observed input aggregate data. In this case, this algorithm is expected to yield the least free energy to the combination of the microwave and refrigerator.

The above description is better understood by way of the following illustration. In the method of the present disclosure, the system 100 obtains softmax information of a plurality of appliances from the first set and the second set of appliances wherein the softmax information is obtained through a softmax function of one visible layer of the RBM. The system also obtains a partition function z serving as an output of another visible layer of the RBM. In other words, the system 100 obtains (i) the softmax information through the softmax function of one visible layer of the RBM connected to the one or more softmax layers and (ii) the partition function z serving as an output of another visible layer of the RBM to the one or more softmax layers (wherein the softmax layers are either integral part of the system 100 or externally connected to the system 100 via the I/O interface(s) 106). The partition function z is obtained based on an input aggregate data fed to one visible layer of the RBM. Both the softmax information and the partition function z are then used as an input to learn combinational outputs of each layer of the RBM. In other words, partition function z of one visible layer of the RBM is added to the softmax information of every softmax layer of the RBM via a function to learn the one or more combinational outputs (e.g., free energy). Such combinational output is learnt by the system 100 via an intermediate function (not shown in FIGS.) implemented in the system 100. In other words, using the intermediate function, one or more combinational outputs of each layer of the RBM is learnt and this learning of the one or more combinational outputs is based on an interaction between the softmax information and the partition function z. The interaction of the softmax information and the partition function z is discussed in the mapping step 208. The combinational outputs (or combinational free energies) are learnt, and these outputs correspond to the input aggregate data. In other words, the during the test phase, the least possible free energy combination of appliances corresponds to the test aggregate data as received (e.g., test smart meter data). By performing the step of obtaining softmax information and partition function and learning the combinational outputs, the present disclosure ensures that there is a reduction in (i) computational efforts/cost(s) by the system and method and (ii) the complexity involved in the architecture. For instance, existing regression-based approaches require multiple instances of the network—one each to learn the aggregate data and appliance data association. The present disclosure is essentially stand-alone RBM which is used in the regressive context for the purpose of load disaggregation. This means that a single RBM is attached with softmax layers and this simplifies the network architecture to a great extent. This architecture obviously helps to also bring computational lightness to the problem of disaggregation.

Present disclosure and its system and method implement a Restricted Boltzmann Machine for load disaggregation of appliance of interest. In approximating the consumption data, RBMs demonstrate good accuracy. When the data is inherently structured, the RBM(s) capture the inherent structure of the data in the form of the partition function and the transformed output bears the same information too. As load consumption behaviour—that is the duration of operation, the pattern in which important appliances are usually operated, the typical duration of operation of appliances of interest—are usually structured, this structure is very important in general load disaggregation. However, any new pattern or appliance inclusion needs adequate/sufficient examples for training of RBM with the same. Generally, Auto Encoders or any other technique as compared to RBM appear to be less optimal in capturing the latent information in the consumption data. Also, the use of extended layers for training appliances seem to require simple (appropriate objective) function for mapping against the input aggregate data using RBM. Auto Encoders on the other hand are reported to use sophisticated iterative techniques to achieve the purpose of disaggregation.

The written description describes the subject matter herein to enable any person skilled in the art to make and use the embodiments. The scope of the subject matter embodiments is defined by the claims and may include other modifications that occur to those skilled in the art. Such other modifications are intended to be within the scope of the claims if they have similar elements that do not differ from the literal language of the claims or if they include equivalent elements with insubstantial differences from the literal language of the claims.

It is to be understood that the scope of the protection is extended to such a program and in addition to a computer-readable means having a message therein; such computer-readable storage means contain program-code means for implementation of one or more steps of the method, when the program runs on a server or mobile device or any suitable programmable device. The hardware device can be any kind of device which can be programmed including e.g., any kind of computer like a server or a personal computer, or the like, or any combination thereof. The device may also include means which could be e.g., hardware means like e.g., an application-specific integrated circuit (ASIC), a field-programmable gate array (FPGA), or a combination of hardware and software means, e.g., an ASIC and an FPGA, or at least one microprocessor and at least one memory with software processing components located therein. Thus, the means can include both hardware means and software means. The method embodiments described herein could be implemented in hardware and software. The device may also include software means. Alternatively, the embodiments may be implemented on different hardware devices, e.g., using a plurality of CPUs.

The embodiments herein can comprise hardware and software elements. The embodiments that are implemented in software include but are not limited to, firmware, resident software, microcode, etc. The functions performed by various components described herein may be implemented in other components or combinations of other components. For the purposes of this description, a computer-usable or computer readable medium can be any apparatus that can comprise, store, communicate, propagate, or transport the program for use by or in connection with the instruction execution system, apparatus, or device.

The illustrated steps are set out to explain the exemplary embodiments shown, and it should be anticipated that ongoing technological development will change the manner in which particular functions are performed. These examples are presented herein for purposes of illustration, and not limitation. Further, the boundaries of the functional building blocks have been arbitrarily defined herein for the convenience of the description. Alternative boundaries can be defined so long as the specified functions and relationships thereof are appropriately performed. Alternatives (including equivalents, extensions, variations, deviations, etc., of those described herein) will be apparent to persons skilled in the relevant art(s) based on the teachings contained herein. Such alternatives fall within the scope of the disclosed embodiments. Also, the words “comprising,” “having,” “containing,” and “including,” and other similar forms are intended to be equivalent in meaning and be open ended in that an item or items following any one of these words is not meant to be an exhaustive listing of such item or items or meant to be limited to only the listed item or items. It must also be noted that as used herein and in the appended claims, the singular forms “a,” “an,” and “the” include plural references unless the context clearly dictates otherwise.

Furthermore, one or more computer-readable storage media may be utilized in implementing embodiments consistent with the present disclosure. A computer-readable storage medium refers to any type of physical memory on which information or data readable by a processor may be stored. Thus, a computer-readable storage medium may store instructions for execution by one or more processors, including instructions for causing the processor(s) to perform steps or stages consistent with the embodiments described herein. The term “computer-readable medium” should be understood to include tangible items and exclude carrier waves and transient signals, i.e., be non-transitory. Examples include random access memory (RAM), read-only memory (ROM), volatile memory, nonvolatile memory, hard drives, CD ROMs, DVDs, flash drives, disks, and any other known physical storage media.

It is intended that the disclosure and examples be considered as exemplary only, with a true scope of disclosed embodiments being indicated by the following claims.

What is claimed is:

1. A processor implemented method, comprising:
receiving, via one or more hardware processors, an input comprising power consumption of a first set of appliances deployed in an infrastructure for a specific time period;
obtaining, via the one or more hardware processors, information pertaining one or more power consumption patterns specific to a second set of appliances;
learning, via a Restricted Boltzmann Machine (RBM) executed by the one or more hardware processors, (i) one or more representations of one or more appliances of interest (AoI), wherein the one or more AoI are subset of at least one of the first set of appliances and the second set of appliances, wherein each softmax layer of the RBM learns a representation of a corresponding AoI from the one or more AoI based on a discriminative output obtained from remaining one or more softmax layers of the RBM;
mapping, via one or more full connected layers of a neural network executed by the one or more hardware processors, the one or more learned representations to a corresponding power consumption pattern from the one or more power consumption patterns to obtain one or more mapped appliance consumption patterns for each of the one or more AoI; and
estimating, via the one or more hardware processors, one or more appliance signatures for the one or more AoI based on the one or more mapped appliance consumption patterns.

2. The processor implemented method of claim 1, wherein the appliance signature is indicative of an identifier and power consumption associated with an AoI from the one or more AoI.

3. The processor implemented method of claim 1, wherein the one or more representations comprise power consumption associated with a corresponding AoI.

4. The processor implemented method of claim 1, further comprising triggering an AoI from the one or more AoI for scheduling on and off based on an appliance signature.

5. The processor implemented method of claim 1, further comprising:
obtaining (i) softmax information of a plurality of appliances from the first set and the second set of appliances, wherein the softmax information is obtained through one visible layer of the RBM connected to the one or more softmax layers, and (ii) a partition function serving as an output of another visible layer of the RBM; and
learning, via an intermediate function, one or more combinational outputs of each layer of the RBM based on an interaction between the softmax information and the partition function.

6. A system, comprising:
a memory storing instructions;
one or more communication interfaces; and
one or more hardware processors coupled to the memory via the one or more communication interfaces, wherein the one or more hardware processors are configured by the instructions to:
receive an input comprising power consumption of a first set of appliances deployed in an infrastructure for a specific time period;
obtain information pertaining one or more power consumption patterns specific to a second set of appliances;
learn, via a Restricted Boltzmann Machine (RBM) executed by the one or more hardware processors, (i) one or more representations of one or more appliances of interest (AoI), wherein the one or more AoI are subset of at least one of the first set of appliances and the second set of appliances, wherein each softmax layer of the RBM learns a representation of a corresponding AoI from the one or more AoI based on a discriminative output obtained from remaining one or more softmax layers of the RBM;
map, via one or more full connected layers of a neural network executed by the one or more hardware processors, the one or more learned representations to a corresponding power consumption pattern from the one or more power consumption patterns to obtain one or more mapped appliance consumption patterns for each of the one or more AoI; and
estimate, via the one or more hardware processors, one or more appliance signatures for the one or more AoI based on the one or more mapped appliance consumption patterns.

7. The system of claim 6, wherein the appliance signature is indicative of an identifier and power consumption associated with an AoI from the one or more AoI.

8. The system of claim 6, wherein the one or more representations comprise power consumption associated with a corresponding AoI.

9. The system of claim 6, wherein the hardware processors are further configured by the instructions to trigger an AoI from the one or more AoI for scheduling on and off based on an appliance signature.

10. The system of claim 6, wherein the hardware processors are further configured by the instructions to:
obtain (i) softmax information of a plurality of appliances from the first set and the second set of appliances, wherein the softmax information is obtained through one visible layer of the RBM connected to the one or more softmax layers, and (ii) a partition function serving as an output of another visible layer of the RBM; and
learn, via an intermediate function, one or more combinational outputs of each layer of the RBM based on an interaction between the softmax information and the partition function.

11. One or more non-transitory machine readable information storage mediums comprising one or more instructions which when executed by one or more hardware processors causes load disaggregation of appliances of interest by:
receiving, via the one or more hardware processors, an input comprising power consumption of a first set of appliances deployed in an infrastructure for a specific time period;
obtaining, via the one or more hardware processors, information pertaining one or more power consumption patterns specific to a second set of appliances;
learning, via a Restricted Boltzmann Machine (RBM) executed by the one or more hardware processors, (i) one or more representations of one or more appliances of interest (AoI), wherein the one or more AoI are subset of at least one of the first set of appliances and the second set of appliances, wherein each softmax layer comprised in the RBM learns a representation of a corresponding AoI from the one or more AoI based on a discriminative output obtained from remaining one or more softmax layers of the RBM;
mapping, via one or more full connected layers of a neural network executed by the one or more hardware processors, the one or more learned representations to a corresponding power consumption pattern from the one or more power consumption patterns to obtain one or more mapped appliance consumption patterns for each of the one or more AoI; and
estimating, via the one or more hardware processors, one or more appliance signatures for the one or more AoI based on the one or more mapped appliance consumption patterns.

12. The one or more non-transitory machine readable information storage mediums of claim 11, wherein the appliance signature is indicative of an identifier and power consumption associated with an AoI from the one or more AoI.

13. The one or more non-transitory machine readable information storage mediums of claim 11, wherein the one or more representations comprise power consumption associated with a corresponding AoI.

14. The one or more non-transitory machine readable information storage mediums of claim 11, wherein the one or more instructions which when executed by the one or more hardware processors further causes triggering an AoI from the one or more AoI for scheduling on and off based on an appliance signature.

15. The one or more non-transitory machine readable information storage mediums of claim 11, wherein the one or more instructions which when executed by the one or more hardware processors further causes:
obtaining (i) softmax information of a plurality of appliances from the first set and the second set of appliances, wherein the softmax information is obtained through one visible layer of the RBM connected to the one or more softmax layers, and (ii) a partition function serving as an output of another visible layer of the RBM; and
learning, via an intermediate function, one or more combinational outputs of each layer of the RBM based on an interaction between the softmax information and the partition function.
